(19) United States
(12) Patent Application Publication
(10) Pub. No.: US 2008/0124234 A1
(43) Pub. Date: May 29, 2008

(54) Fan tray assembly shaped Venturi

(76) Inventor: Jaime Echazarreta, Chula Vista, CA (US)

Correspondence Address: BROMBERG & SUNSTEIN LLP, 125 SUMMER STREET, BOSTON, MA, 02110-1618, US

(21) Appl. No.: 11/592,030

(22) Filed: Nov. 2, 2006

(51) Int. Cl. F04D 29/54; H05K 7/20

(52) U.S. Cl. 417/423.14; 361/695; 417/360; 417/424.1; 415/219.1

(57) ABSTRACT

A fan trays assembly is made of one or small number of cast or injection molded (collectively “cast”) components. Each component can be cast of plastic, metal or another material. One of the components of the fan tray includes a front wall, a back wall, two side walls, an inner wall defining a Venturi and a motor housing suspended within the Venturi by one or more structural members. The walls, the motor housing and the structural member(s) are all formed as a single casting. Casting these pieces together reduces the complexity and cost of manufacturing the fan trays. Multi-fan fan trays and modular fan trays can be similarly made.

### BACKGROUND ART

The present invention relates to equipment cooling fans and, more particularly, to cooling fan trays.

Electronic and other devices, such as telecommunications equipment, audiovisual equipment and rack-mounted computer equipment (such as “blade” systems), generate heat that must be dissipated to avoid damage to the devices. Fans are commonly used to force cooling air through the devices. To facilitate replacing a failed or failing fan, the fans are typically mounted in removable trays. FIGS. 1 and 2 illustrate a typical prior-art single-fan tray, and FIG. 3 illustrates a typical prior-art multi-fan tray.

Conventional fan trays are constructed of sheet metal. Conventional fan trays are, however, time-consuming and expensive to manufacture. The sheet metal must be stamped, bent, welded, degreased, polished, etc., and the individual fan units must be installed in the fan trays.

### SUMMARY OF THE INVENTION

An embodiment of the present invention provides a fan tray component. The fan tray component includes a front wall, a back wall, and two side walls. Each of the side walls is connected to the front wall and to the back wall. The front wall, the back wall and the two side walls define a volume. The fan tray component also includes a first inner wall that is at least partially disposed within the volume. The first inner wall defines a Venturi. The fan tray component also includes a first motor housing. The front wall, the back wall, the two side walls, the first inner wall and the first motor housing are formed as a single casting.

The first inner wall may be connected by at least one first structural member to at least one of the front wall, the back wall, one of the two side walls and/or the other of the two side walls. The fan tray may also include at least one second structural member that connects the first motor housing to the first inner wall. The at least one second structural member may suspend the first motor housing within the Venturi. The at least one first structural member, the at least one second structural member and the front wall are formed as a single casting.

The fan tray component may also include an electrical connector mounted to the back wall. The electrical connector may include at least four terminals. The electrical connector can be a blind-mating connector.

The fan tray component may include an electric motor dispose within the first motor housing and electrically connected to the electrical connector. A rotor may be attached to the electric motor, such that when the electric motor operates, the electric motor rotates the rotor.

The fan tray component may also include a circuit board that has electrical components electrically connected to the electrical connector and to the electric motor. The electrical components control a rotational speed of the electric motor. At least one of the electrical components may be operative to receive signals, via the electrical connector, to control the rotational speed of the electric motor. The signals may conform to an inter-integrated circuit (I2C) protocol or to a controller area network (CAN) protocol.

The fan tray component may also include a handle adjacent the front wall. The handle and the front wall may be formed as a single casting. Alternatively, the handle may be attached to the front wall by at least one fastener.

The fan tray component may also include a latch mechanism. The latch mechanism may be adjacent the back wall. Alternatively, the latch mechanism may be adjacent one of the two side walls.

The fan tray component may also include a grill adjacent one end of first inner wall. The fan tray component may also include a filter receiving element.

The back wall may be parallel to the front wall. The two side walls may be perpendicular to the front wall and to the back wall. Alternatively, the walls may be oriented differently, such as at angles other than 90° to each other.

The fan tray component may include a mounting bracket adjacent one of the side walls and extending along at least part of the length of the side wall, such as along a line between the front wall and the back wall. The mounting bracket may have a first predefined cross-sectional profile, such as when the cross-section is taken perpendicular to the length of the side wall. The other side wall of the fan tray component may define a mounting bracket receiver that extends along at least part of the length of the side wall, such as along a line between the front wall and the back wall. The mounting bracket receiver may have a second predefined cross-sectional profile, such as when the cross-section is taken perpendicular to the length of the side wall. The first cross-sectional profile (of the mounting bracket) may be complementary to the second cross-sectional profile (of the mounting bracket receiver).

The back wall of the fan tray component may define a mounting bracket receiver that has a first predefined cross-sectional profile.

The fan tray component may also include a mounting bracket adjacent the front wall and that has a predefined cross-sectional profile.

The fan tray may have a second inner wall at least partially disposed within the volume. The s inner wall may define a second Venturi. The second inner wall may be connected by at least one third structural element to the front wall, the back wall, one of the two side walls, the other of the two side walls, the first inner wall or combination thereof.

The fan tray may include a second motor housing. The fan tray may also include at least one fourth structural element that connects the second motor housing to the second inner wall. The first inner wall and the second inner wall are formed as a single casting.

Another embodiment of the present invention provides a fan tray component that includes a first component joined to a second component. The first component includes a first front wall, a first back wall and two first side walls. Each first side wall is connected to the first front wall and to the first back wall. The first front wall, the first back wall and the two first side walls define a volume. The first component also includes an inner wall that is at least partially disposed within the volume. The inner wall defines a Venturi. The first component also includes a motor housing that is at least partially disposed within the Venturi. The first front wall, the first back wall, the first two side walls, the first inner wall and the motor housing are formed as a single casting. The first component defines at least one void.

The second component includes a second front wall, a second back wall and two second side walls. Each second side wall is connected to the second front wall and to the second back wall. The second front wall, the second back wall and the two second side walls are formed as a single casting. The first component and/or the second component further also includes at least one block located to prevent air from flowing through the at least one void.

Yet another embodiment of the present invention provides a modular fan tray component that includes a front wall, a back wall and two side walls, Each side wall is connected to the front wall and to the back wall. The front wall, the back wall and the two side walls define a volume. The fan tray component also includes a first inner wall at least partially disposed within the volume. The first inner wall defines a Venturi. The fan tray component also includes a fan that is at least partially disposed within the Venturi. The fan tray component also includes a first mounting bracket adjacent one of the two side walls. The first mounting bracket has a first predefined cross-sectional profile. The other of the two side walls defines a first mounting bracket receiver that has a second predefined cross-sectional profile.

The first cross-sectional profile may be complementary to the second cross-sectional profile.

The back wall may define a second mounting bracket receiver that has a third predefined cross-sectional profile.

The other of the two side walls may have a length that extends from the front wall to the back wall, and the first mounting bracket receiver may extend along at least part of the length of the other of the two side walls. The back wall may have a length extending from one of the two side walls to the other of the two side walls, and the second mounting bracket receiver may extend along at least part of the length of the back wall.

The modular fan tray component may also include a second mounting bracket adjacent the front wall. The second mounting bracket may have a fourth predefined cross-sectional profile.

The third cross-sectional profile may be complementary to the fourth cross-sectional profile.

Another embodiment of the present invention provides a dummy modular fan tray component that includes a front wall, a back wall and two side walls. Each side wall is connected to the front wall and to the back wall. The front wall, the back wall and the two side walls define an area. The dummy modular fan tray also includes a partition that blocks air flow through the area. The dummy modular fan tray also includes a first mounting bracket adjacent one of the two side walls. The first mounting bracket has a predefined cross-sectional profile. The other of the two side walls defines a first mounting bracket receiver that has a predefined cross-sectional profile.

### BRIEF DESCRIPTION OF THE DRAWINGS

The invention will be more fully understood by referring to the following Detailed Description of Specific Embodiments in conjunction with the Drawings, of which:

FIG. 1 is a perspective front view of a prior-art, single-fan fan tray;

FIG. 2 is a perspective rear view of the prior-art fan tray of FIG. 1;

FIG. 3 is a perspective front view of a prior-art, multi-fan fan tray;

FIG. 4 is a perspective front view of a fan tray according to one embodiment of the present invention;

FIG. 5 is a perspective rear view of the fan tray of FIG. 4;

FIG. 6 is a perspective front view of a fan tray according to another embodiment of the present invention;

FIG. 7 is a perspective front view of a fan tray according to yet another embodiment of the present invention;

FIG. 8 is a perspective exploded front view of the fan tray of FIG. 7;

FIG. 9 is a perspective cut-away front view of the fan tray of FIG. 7;

FIG. 10 is a cross-sectional view of a portion of the fan tray of FIG. 7;

FIG. 11 is a perspective front view of a multi-fan fan tray according to an embodiment of the present invention;

FIG. 12 is a perspective front view of a modular fan tray according to an embodiment of the present invention;

FIG. 13 is a perspective side view of a vertically-oriented fan tray according to an embodiment of the present invention; and

FIG. 14 is a perspective side view of a vertically-oriented fan tray according to another embodiment of the present invention.

### DETAILED DESCRIPTION OF SPECIFIC EMBODIMENTS

In accordance with one embodiment of the present invention, a fan trays assembly is made of one or a small number of cast or injection molded (collectively “cast”) components. Each component can be cast of plastic, metal or another material. For example, in one embodiment, one of the components of the fan tray includes a front wall, a back wall, two side walls, an inner wall defining a Venturi and a motor housing suspended within the Venturi by a structural member. The walls, the motor housing and the structural member are all formed as a single casting. Casting these pieces together reduces the complexity and cost of manufacturing the fan trays.

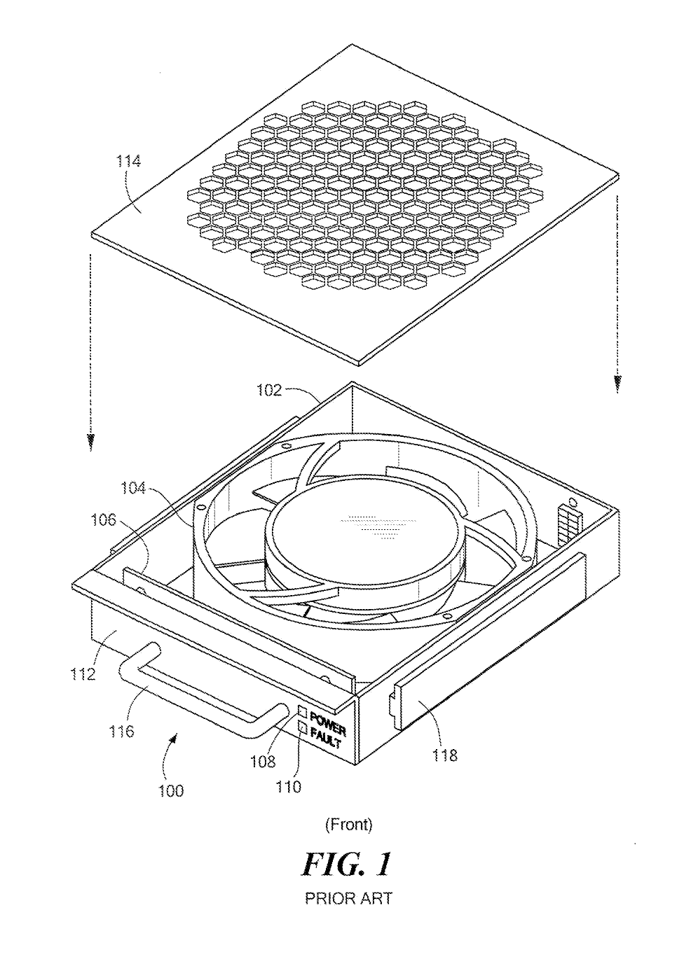

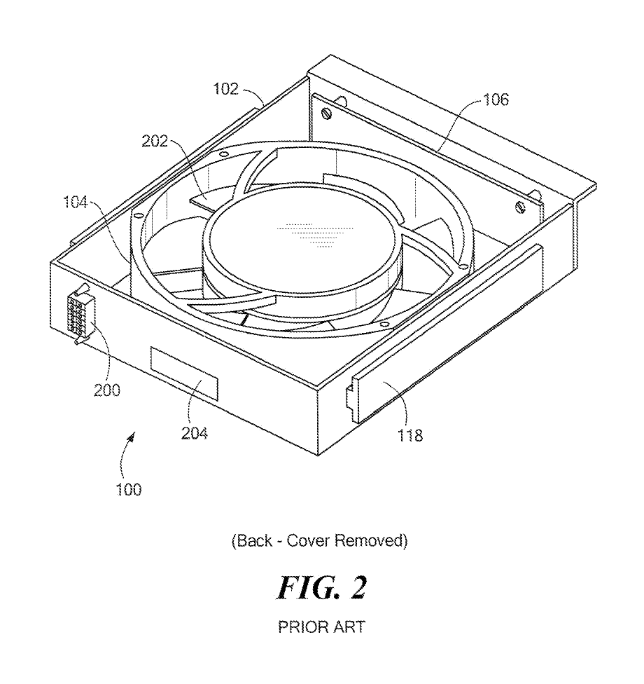

FIGS. 1 and 2 show front and back views, respectively, of a conventional (i.e., prior art) single-fan tray 100. The tray 100 includes a metal chassis 102, which is fabricated from sheet metal. The sheet metal is typically stamped, bent, welded or riveted or screwed together, degreased and polished. A discrete fan unit 104 is housed in the chassis 102. The fan unit 104 is a generic device, i.e., it is capable of being mounted in a number of different contexts. For this reason, the fan unit 104 includes its own structural frame, which defines a Venturi.

The fan unit 104 is attached to the metal chassis 102, such as by sheet metal screws (not shown). Optionally, a grill or other cover 114 is attached to the chassis 102. The fan tray 100 also includes a handle 116 that facilitates installing/removing the fan tray 100 into/from a device that the fan tray 100 is to cool. Optionally, the fan tray 100 includes side rails 118 (one of which is not visible in FIG. 1) that cooperate with receiving rails in the device that the fan tray 100 is to cool. Each receiving rail typically defines an appropriately shaped opening, into which the corresponding side rail 118 slides.

As shown in FIG. 2, an electrical connector 200 is attached to a back wall of the chassis 102. Power is provided to the fan tray 100 via the connector 200. The chassis 102 also houses a printed circuit board 106 that is connected to the connector 200 and to the fan unit 104 via wires (not shown). The circuit board 106 includes electronic components, which control operation of the fan unit 104. Optionally, control signals are sent and/or received via the connector 200. For example, the fan tray 100 can receives signals to control the speed of the rotor 202 of the fan unit 104 or to report status of the fan tray 100. The fan tray 100 also typically includes a latch 204 on a back of the fan tray or, alternatively, on the side(s) (not shown) of the fan tray 100.

Returning to FIG. 1, optionally, the printed circuit board 106 controls indicators, such as a power indicator 108 and a fault indicator 110, that are visible on a front panel 112 of the fan tray 100.

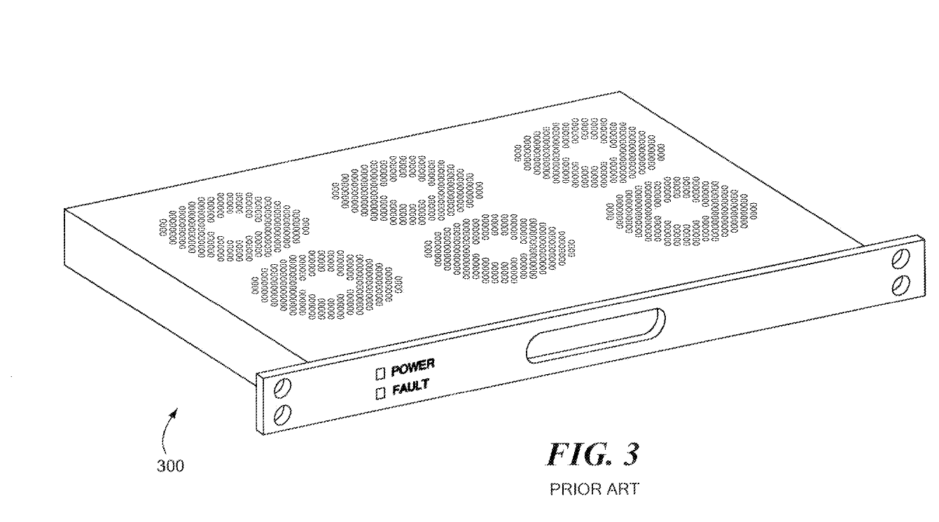

FIG. 3 shows a conventional multi-fan tray 300. Construction of the multi-fan tray 300 is similar to the single-fan tray 100, except the multi-fan tray 300 includes a plurality of individual fan units, each separately attached to the chassis. As noted, convention fan trays are expensive and time-consuming to manufacture, because of the number of steps required. In addition, the individual fan units used in conventional fan trays add unnecessary material, weight and cost the fan trays. These and other disadvantages of the prior art are avoided by fan trays constructed according to the present disclosure.

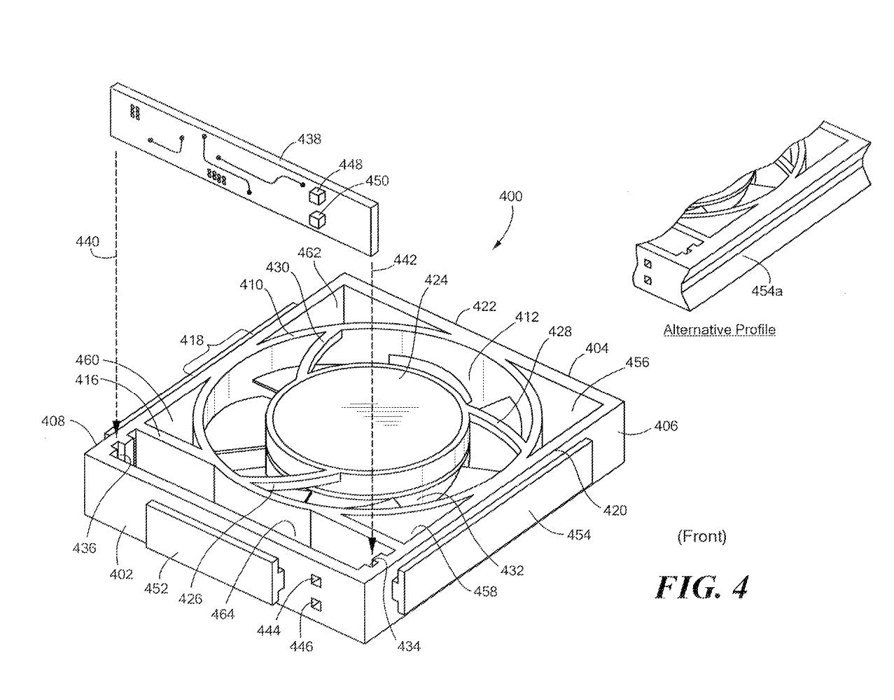

FIG. 4 is a front view of one embodiment of a fan tray 400, according to the present invention. The fan tray 400 includes a front wall 402, a back wall 404 and two side walls 406 and 408. The walls 402-408 are cast as a single unit and can be made of plastic (such as liquid crystal polymer), metal (such as steel or aluminum) or any other suitable material.

The fan tray 400 also includes a curved inner wall 410 that defines a Venturi 412. The inner wall 410 is cast at the same time, and of the same material, as the walls 402-408. Thus, the walls 402-408 and the inner wall 410 form a single, integrated unit. In the embodiment shown in FIG. 4, the inner wall 410 is circular; however, in other embodiments, the inner wall 410 can have other shapes.

In the embodiment shown in FIG. 4, the inner wall 410 is attached to the side walls 406 and 408 by structural members 414 and 416. In addition, the inner wall 410 joins the side wall 408 in a region 418. Similarly, the inner wall 410 joins the other side wall 406 and the back wall 404 in similar regions 420 and 422, respectively. The regions 418-422 are also refer to herein as “structural members.” The structural members 414-422 are cast at the same time, and of the same material, as the inner wall 410 and the other cast portions of the fan tray 400. Thus, the structural members 414-422, the inner wall 410 and the other cast portions of the fan tray 400 form a single, integrated unit. In other embodiments, other numbers of structural members can be used. In addition, in other embodiments, the structural member(s) can connect the inner wall 410 to any one or more of the walls 402-408.

The fan tray 400 also includes a motor housing 424. Three additional structural members 426, 428 and 430 connect the motor housing 424 to the inner wall 410, thus suspending the motor housing 424 within the Venturi 412. The motor housing 424 and the structural members 426-430 are cast at the same time, and of the same material, as the inner wall 410 and the other cast portions of the fan tray 400. Thus, motor housing 424, the structural members 426-430, the inner wall 400 and the other cast portions of the fan tray 400 form a single, integrated unit. Other numbers of structural members can be used to connect the motor housing 424 to the inner wall 410 and suspend the motor housing 424 within the Venturi 412.

An electric motor (not visible) is disposed within the motor housing 424 and coupled to a rotor 432 having one or more blades. Thus, when the electric motor operates, the rotor rotates, and the blades force air through the fan tray 400. Fabricating a fan tray 400 with an integrated motor housing 424 obviates the need for a discrete fan unit with its own structural frame, as is used in the prior art. The walls 402-408, the inner wall 410 and the structural members 414-422 all structurally reinforced each other. Thus, the fan tray 400 can be stronger, lighter in weight and/or contain less material than a prior art fan tray that includes a discrete fan unit.

The side walls 406 and 408 define channels 434 and 436, into which a printed circuit board 438 can be received, as indicated by arrows 440 and 442. Optionally, the front wall 402 defines openings 444 and 446, and the printed circuit board 438 includes indicators 448 and 450 that register with the openings 444 and 446 when the printed circuit board 438 is inserted into the channels 434 and 436. The printed circuit board 438 includes electrical components that are connected to the electric motor via wires (not visible). The wires can, for example, pass through the structural members 414 or 416 and 426. The electrical components supply power to, and therefore can control the rotational speed of, the electric motor, as is well known in the art.

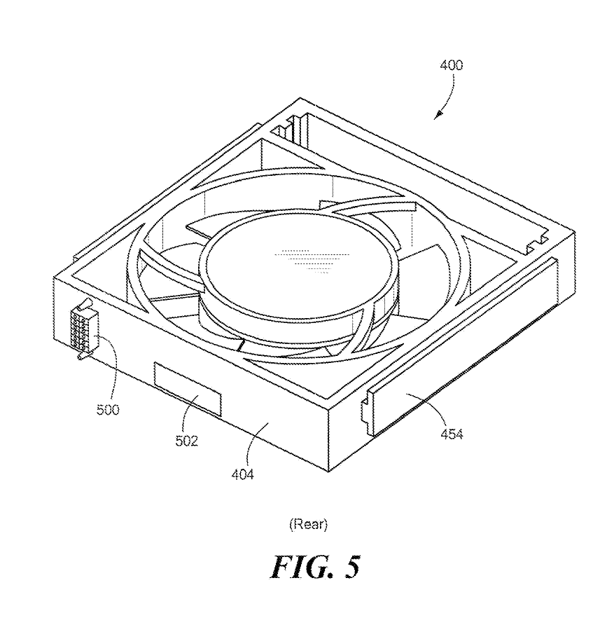

FIG. 5 is a rear view of the fan tray 400. A multi-terminal electrical connector 500 is mounted to the back wall 404. The electrical connector 500 is connected via wires (not shown) to the electric motor and/or the printed circuit board 438 (omitted from FIG. 4 for clarity). The electrical connector 500 is preferably a “blind-mate” connector, which is well-known in the art. A blind-mate connector can, but need not, include a mating guide (such as a flange, a funnel or a guidepost) that helps align the electrical connector 500 with a corresponding connector in the device that is to be cooled by the fan tray 400 when the fan tray is inserted into the device. The electrical connector 500 can, but need not, be of the “floating” type, i.e., the x and y coordinates of the electrical connector 500 need not be rigidly fixed, with respect to the back wall 404 of the fan tray 400.

Optionally, the fan tray 400 can communicate with control circuitry in the device that the fan tray 400 is to cool. For example, the circuit board 438 can include components that communicate with the control circuitry according to a protocol, such as the well-known inter-integrated circuit (I2C) protocol. In this case, the electrical connector 500 includes a number of pins that carry messages according to the protocol. In some embodiments, the electrical connector 500 includes a pin for each of: I2C data, I2C clock, power and ground. Any other suitable protocol, such as Controller Area Network (CAN), Bluetooth or RS232, can be use. In each of these cases, the electrical connector 500 may have a suitable number of pins.

Returning to FIG. 4, the fan tray 400 optionally includes a handle 452. The handle 452 can be molded along with the front wall 402, i.e., the handle 452 and the front wall 402 can be formed as a single casting. Alternatively, the handle 452 can be separate from the front wall 402. In this case, the handle 452 is attached to the front wall 402, such as by at least one fastener. This fastener can be a screw, a rivet, a boss projecting from the front wall 402 onto which the handle 452 is pressed (or vice versa), an adhesive or any other appropriate fastener.

Optionally, the fan tray 400 includes one or more side rails (mounting brackets), one of which is visible at 454, for mounting the fan tray 400 in a device that is to be cooled. The mounting brackets 454 are adjacent the side walls 406 and 408, respectively, and extend along at least part of the length of the side walls 406 and 408, i.e., along a line from the front wall 402 to the back wall 404. Each mounting bracket 454 has a predefined cross-sectional profile. An alternative profile is shown at 454a. Other portfolios can, of course, be used. In addition, the mounting brackets 454 need not be aligned along a line extending from the front wall 402 to the back wall 404; instead, the mounting brackets 454 can be aligned along any convenient line. Each mounting bracket 454 can slide into a complementary-shaped opening in the device that the fan tray 400 is to cool. For example, the mounting bracket 454 can have a male profile, and the device can have a complementary female profile.

The side rails 454 can be molded along with the side walls 406-408, i.e., each side rail 454 and the corresponding side wall 406 or 408 are formed as a single casting. Alternatively, the side rails 454 can be separate from the side walls 406-408. In this case, the side rails 454 are attached to the side walls 406 and 408, respectively, such as by at least one fastener, as described above with respect to the handle 452.

As shown in FIG. 5, a latch 502 is attached to the back wall 404 of the fan tray 400. The latch 502 secures the fan tray 400, after the fan tray 400 has been inserted into the device that it is to cool. The latch 502 can be any suitable type, such as a detent-type latch, which can be overcome by applying a sufficient pulling force on the handle 452. Alternatively, a manual or remotely-controlled release latch can be used. In this case, the fan tray 400 can include a release lever (not shown) on the front wall 402, on the handle 452 or in another suitable location. In other embodiments, the latch can be attached to one or both side walls 406 and/or 408 or to other portions of the fan tray 400 instead of or in addition to the back wall 404.

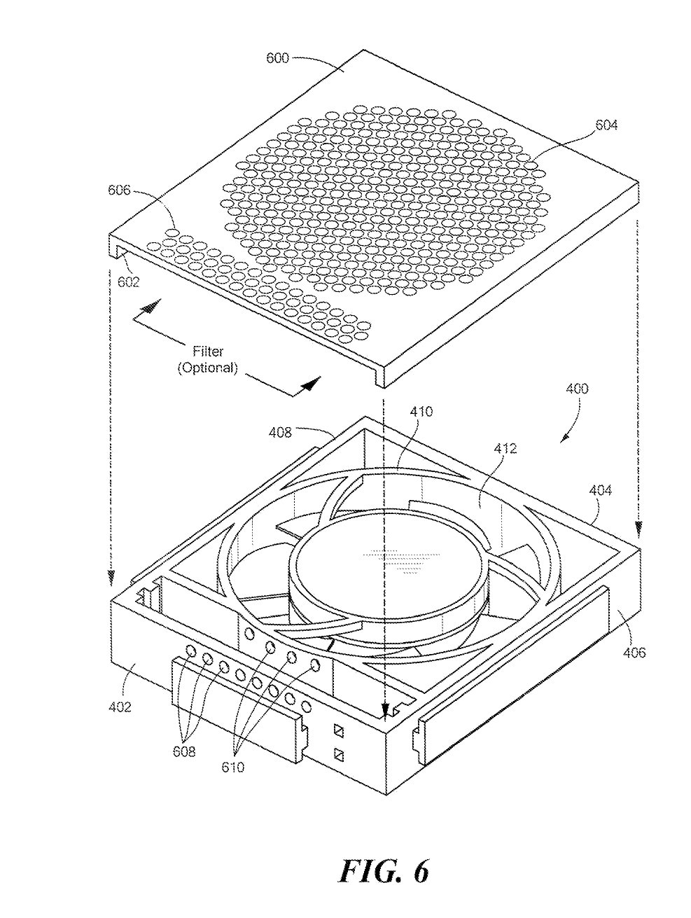

Optionally, a grill and/or filter can be attached to the fan tray 400, as shown in FIG. 6. A grill 600 can be attached to the top and/or bottom of the fan tray 400. Optionally, the grill 600 includes a stepped portion 602 that accepts a filter element (not shown). In one embodiment, the grill 600 is perforated to form an air-flow area 604 approximately the same size and shape as the Venturi 412 defined by the inner wall 410. The grill 600 is configured such that, when the grill 600 is attached to the fan tray 400, the airflow area 604 registers with the Venturi 412. Alternatively, the grill 600 can be partially or entirely made of a screen or mesh material.

The grill 600 can be made of plastic, metal or any other suitable material, and the grill 600 can be attached to the fan tray 400 by any suitable mechanism. For example, if the grill 600 is plastic, the grill 600 can be ultrasonically welded to the edges of the walls 402-408 of the fan tray 400. Alternatively, the grill 600 can be fastened to the edges of the walls 402-408 by self-tapping screws.

Optionally, the grill 600 includes a second air-flow area 606 to provide ventilation for the circuit board 438. Alternatively or optionally, the front wall 402 and/or the inner wall 410 include one or more holes 608 and 610, respectively, to force cooling air over the circuit board 438 (not shown).

Returning again to FIG. 4, the walls 402-408, the inner wall 410 and the structural members 414-416 define hollow sections (“voids”) 456, 458, 460, 462 and 464. Other configurations of the inner wall 410 and/or other numbers or other configurations of the structural members may define other numbers and/or shapes of voids. Preferably, the voids 460-464 do not extend all the way from the top to the bottom of the fan tray 400. That is, the fan tray 400 includes blocks that prevent air from flowing through the voids 460-464.

The circuit board 438 occupies at least part of the void 464. It may be desirable for air to flow through the void 464 to cool the circuit board 438. In that case, the void 646 can be unblocked or only partially blocked. In either case, the walls 402-408 define a rectangular area above and below the fan tray 400. Air is drawn into one of these rectangular areas (an intake area) and exhausted through the other of the two rectangular areas (an exhaust area) by the rotating blades attached to the rotor 432. The inner wall 410 defines a Venturi 412 having a cross-sectional area that is smaller than the intake area or the exhaust area.

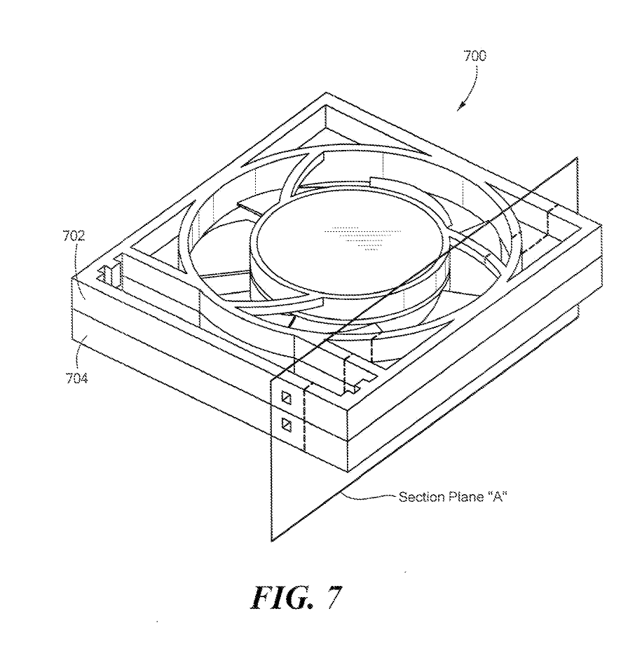

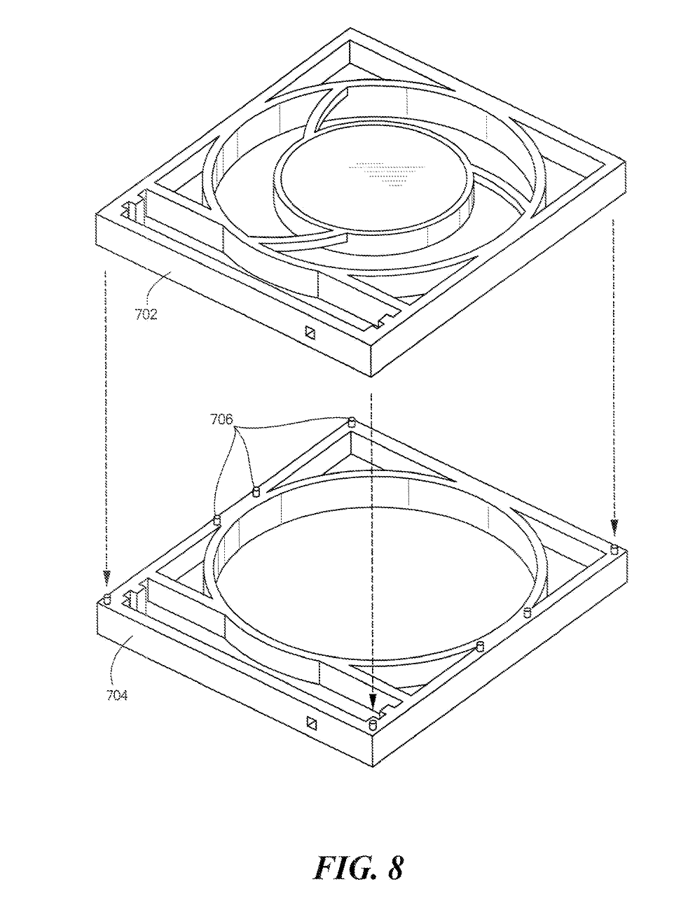

This difference in cross-sectional areas is provided largely by the above-mentioned blocks. To facilitate fabricating a fan tray that includes such blocks, the fan tray can be cast as two separate components. FIG. 7 shows one embodiment of a fan tray 700 that is cast as two separate components 702 and 704. FIG. 8 shows the two components 702 and 704 before they are joined together. The two components 702 and 704 can be joined together by any suitable mechanism, such as an adhesive, ultrasonic welding or pins 706 on one of the two components 702 or 704 that press fit into corresponding holes (not visible) in the other of the two components.

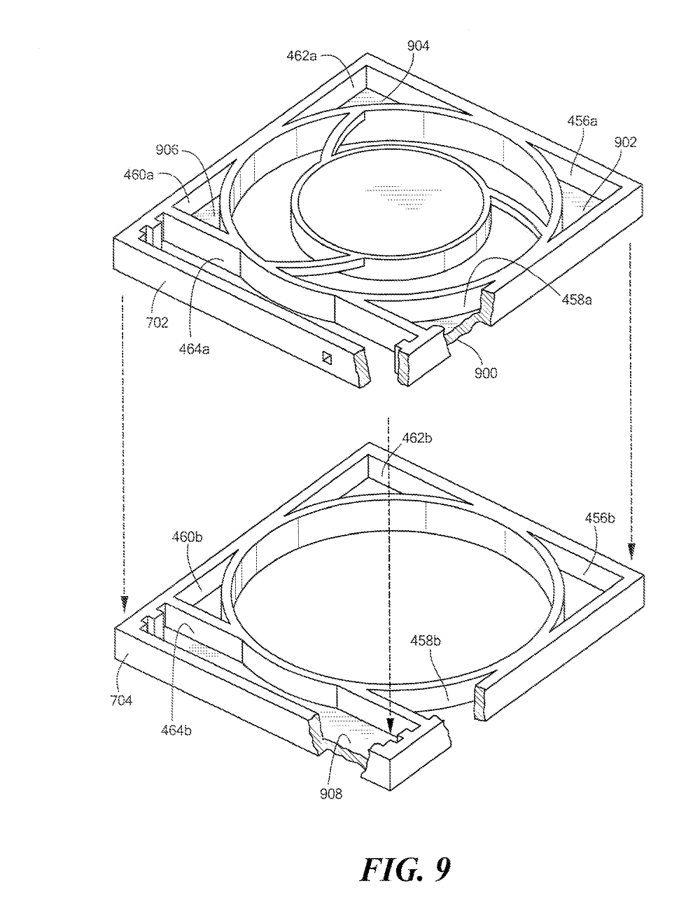

FIG. 9 similarly shows the two components 702 and 704 before they are joined together. Each of the voids 456-464 extends at least partly through the top component 702 of the fan tray 700. Some of the voids 456-464 may extend all the way through the top component 702. As shown in the top part of FIG. 9, the top part of the void 464 (labeled 464a in FIG. 9) extends all the way through the top component 702. On the other hand, as shown in a top part of FIG. 9, the top part of the void 458 (labeled 458a in FIG. 9) does not extend all the way through the top portion 702, because the top portion 702 includes a floor 900 at the bottom of the void 458a. Similarly, the top portion 702 includes floors 902, 904 and 906 to prevent air from flowing through the voids 456-462.

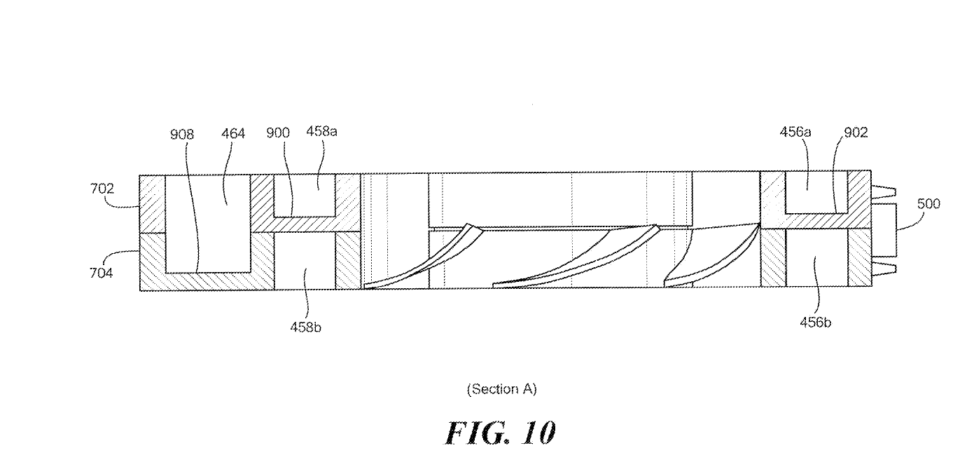

The top portion 702 does not include a floor to prevent air from flowing through the void portion 464a. The bottom portion 704 includes a floor 908 to prevent air from flowing all the way through the void 464. However, because the floors 900-906 prevent air from flowing through the respective void portions 456a-462a of the top portion 702, the bottom portion 704 need not include floors for void portions 456b-462b. This is also visible in a cross-section A (shown in FIG. 10) of the two components 702 and 704. (A corresponding section plane A is shown in FIG. 7.)

Although a fan tray 700 made up of two components 702 and 704 is described, in other embodiments, the fan tray 700 can be made up of other numbers of components. For example, the fan tray 400 shown in FIGS. 4, 5 and 6 can be cast as a single component. On the other hand, a fan tray can also be made of more than two components.

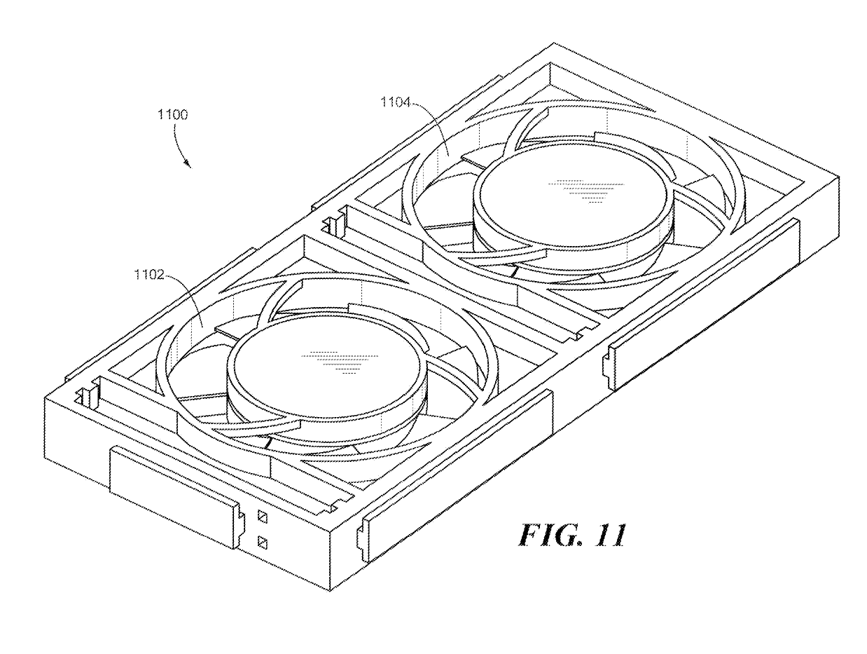

Thus far, a fan tray 400 or 700 that includes a single fan has been described. However, in other embodiments of the present invention, a fan tray can include more than one fan. For example, as shown in FIG. 11, a fan tray 1100 includes two fans 1102 and 1104. Other embodiments can include other numbers of fans, and the fans can be arranged in any pattern. Most other aspects of the multi-fan fan tray 1100 are similar to the fan trays 400 and 700 described above.

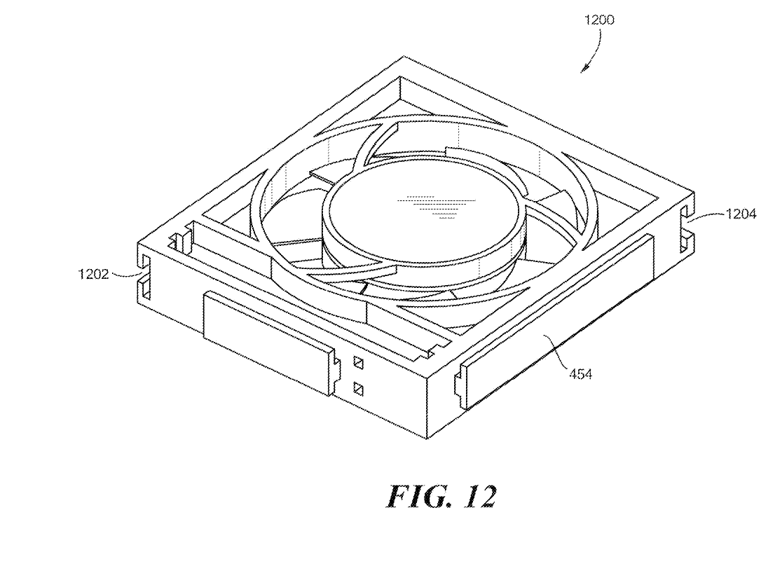

Modular fan tray units can also be constructed, according to another embodiment of the present invention. For example, as shown in FIG. 12, a fan tray 1200 includes a side rail 454 on one side, as described above. However, on the other side, the fan tray 1200 defines a complementary-shaped opening (also referred to as a side rail receiver or a mounting bracket receiver) 1202, into which the side rail 454 of another fan tray (not shown) can be slid, thus forming a multi-fan tray. Preferably, the side rail 454 and the opening 1202 interlock when the side rail 454 is slid into the opening 1202; however, interlocking rails and openings are not necessary.

Optionally, the rear wall of the fan tray 1200 also includes a similar opening (also referred to as a front rail receiver or a mounting bracket receiver) 1204. In this case, another fan tray (not shown) that includes a front rail (instead of a handle) can be joined to the rear of the fan tray 1200. By this mechanism, a fan tray consisting of any number of desired fans, arranged in any desired pattern, can be easily assembled by an end user or system administrator.

Although the side rail 454, the side rail receiver 1202 and the front rail receiver 1204 are shown as being horizontally oriented, i.e., parallel to the plane of the fan tray 1200, the side rail 454 and the rail receivers 1202-1204 can be oriented along other lines.

“Dummy” fan trays (not shown) can also be provided. A dummy fan tray has a side and/or a front rail and mounting bracket receiver(s), as described above. However, the dummy fan tray does not include a fan; instead, the dummy fan tray includes a partition to block airflow through an area defined by the front, back and side walls. A combination of real and dummy fan trays can be assembled to meet a current cooling or airflow requirement. Later, if the requirement increases, one or more of the dummy fan trays can be replaced with real fan trays.

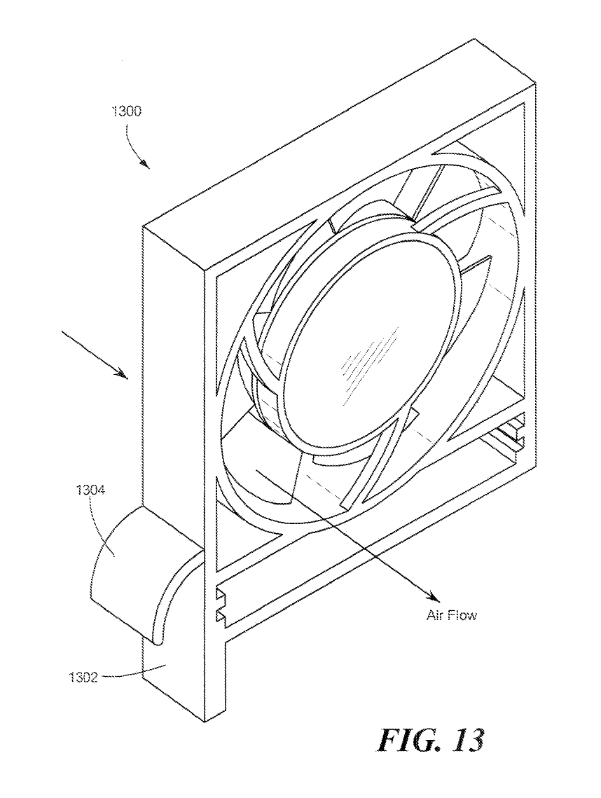

FIG. 13 shows a vertically-oriented fan tray 1300, according to another embodiment of the present invention. The front wall 1302 includes a handle 1304, by which the fan tray 1300 can be inserted into, or remove from, a device that the fan tray 1300 is to cool.

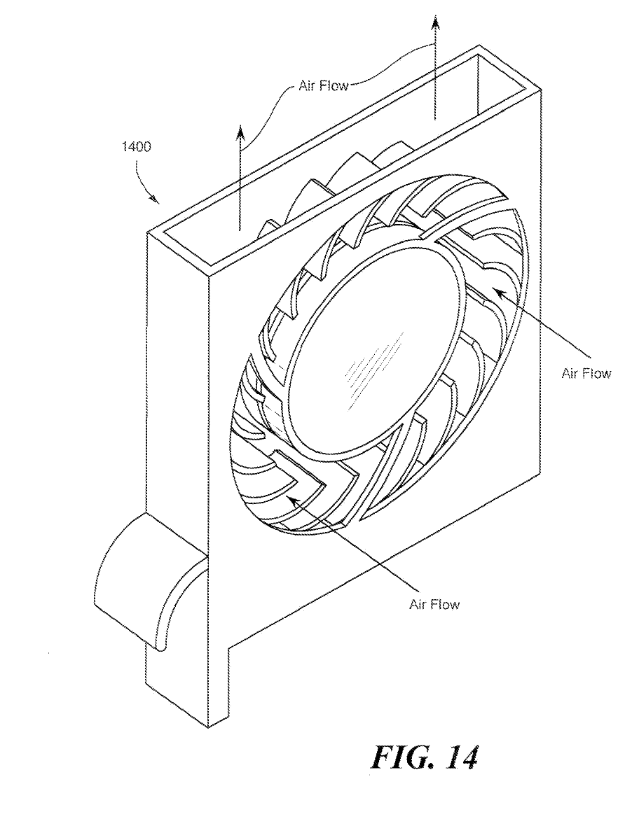

FIG. 14 shows a vertically-oriented fan tray 1400, according to yet another embodiment of the present invention. In this embodiment, a squirrel cage fan is used to direct air at a right angle to the air intake direction.

While the invention is described through the above-described exemplary embodiments, it will be understood by those of ordinary skill in the art that modifications to, and variations of, the illustrated embodiments may be made without departing from the inventive concepts disclosed herein. For example, although rectangular fan trays have been described, other embodiments of the inventive fan tray can be made in other shapes. For example, pie-section shaped fan trays (i.e., fan trays with angled side walls) can be used in circular devices. Moreover, while the preferred embodiments are described in connection with various illustrative materials and manufacturing processes, one skilled in the art will recognize that other materials and/or manufacturing processes may be employed. Accordingly, the invention should not be viewed as limited, except by the scope and spirit of the appended claims.

What is claimed is:

1. A fan tray component, comprising:
a front wall;
a back wall;
two side walls, each side wall being connected to the front wall and to the back wall; the front wall, the back wall and the two side walls defining a volume;
a first inner wall at least partially disposed within the volume and defining a Venturi; and
a first motor housing at least partially disposed within the Venturi;
wherein the front wall, the back wall, the two side walls, the first inner wall and the first motor housing are formed as a single casting.

2. A fan tray component as defined in claim 1, further comprising:
at least one first structural member connecting the first inner wall to at least one of the front wall, the back wall, one of the two side walls and the other of the two side walls; and
at least one second structural member connecting the first motor housing to the first inner wall and suspending the first motor housing within the Venturi;
wherein the at least one of first structural member, the at least one second structural member and the front wall are formed as a single casting.

3. A fan tray component as defined in claim 1, further comprising an electrical connector mounted to the back wall.

4. A fan tray component as defined in claim 3, wherein the electrical connector includes at least four terminals.

5. A fan tray component as defined in claim 3, wherein the electrical connector is a blind-mating connector.

6. A fan tray component as defined in claim 3, further comprising:
an electric motor dispose within the first motor housing and electrically connected to the electrical connector; and
a rotor attached to the electric motor, such that when the electric motor operates, the electric motor rotates the rotor.

7. A fan tray component as defined in claim 6, further comprising a circuit board having electrical components electrically connected to the electrical connector and to the electric motor and operative to control a rotational speed of the electric motor.

8. A fan tray component as defined in claim 7, wherein at least one of the electrical components is operative to receive signals, via the electrical connector, to control the rotational speed of the electric motor.

9. A fan tray component as defined in claim 8, wherein the signals conform to an inter-integrated circuit (I2C) protocol.

10. A fan tray component as defined in claim 8, wherein the signals conform to a controller area network (CAN) protocol.

11. A fan tray component as defined in claim 1, further comprising a handle adjacent the front wall.

12. A fan tray component as defined in claim 11, wherein the handle and the front wall are formed as a single casting.

13. A fan tray component as defined in claim 11, wherein the handle is attached to the front wall by at least one fastener.

14. A fan tray component as defined in claim 1, further comprising a latch mechanism.

15. A fan tray component as defined in claim 14, wherein the latch mechanism is adjacent the back wall.

16. A fan tray component as defined in claim 14, wherein the latch mechanism is adjacent one of the two side walls.

17. A fan tray component as defined in claim 1, further comprising a grill adjacent one end of first inner wall.

18. A fan tray component as defined in claim 1, further comprising a filter receiving element.

19. A fan tray component as defined in claim 1, wherein the back wall is parallel to the front wall.

20. A fan tray component as defined in claim 1, wherein the two side walls are perpendicular to the front wall and to the back wall.

21. A fan tray component as defined in claim 1, wherein at least one of the two side walls has a length extending from one end thereof to another end thereof, and
further comprising a mounting bracket adjacent the side wall and extending along at least part of the length of the side wall, the mounting bracket having a first predefined cross-sectional profile when the cross-section is taken perpendicular to the length of the side wall.

22. A fan tray component as defined in claim 21, wherein the other of the two side walls:
has a length extending from one end thereof to another end thereof; and
defines a mounting bracket receiver extending along at least part of the length of the side wall, the mounting bracket receiver having a second predefined cross-sectional profile when the cross-section is taken perpendicular to the length of the side wall.

23. A fan tray component as defined in claim 22, wherein the first cross-sectional profile is complementary to the second cross-sectional profile.

24. A fan tray component as defined in claim 21, wherein the back wall defines a mounting bracket receiver having a first predefined cross-sectional profile.

25. A fan tray component as defined in claim 24, further comprising a mounting bracket adjacent the front wall and having a second predefined cross-sectional profile.

26. A fan tray component as defined in claim 1, further comprising:
a second inner wall at least partially disposed within the volume and defining a second Venturi, the second inner wall being connected by at least one third structural element to at least one of the front wall, the back wall, one of the two side walls, the other of the two side walls and the first inner wall;
a second motor housing; and
at least one fourth structural element connecting the second motor housing to the second inner wall;
wherein the first inner wall and the second inner wall are formed as a single casting.

27. A fan tray, comprising:
a first component, comprising:
a first front wall;
a first back wall;
two first side walls, each first side wall being connected to the first front wall and to the first back wall; the first front wall, the first back wall and the two first side walls defining a volume;
an inner wall at least partially disposed within the volume and defining a Venturi; and
a motor housing at least partially disposed within the Venturi;
wherein the first front wall, the first back wall, the first two side walls, the first inner wall and the motor housing are formed as a single casting; and
wherein the first component defines at least one void; and
a second component joined to the first component, the second component comprising:
a second front wall;
a second back wall;
two second side walls, each second side wall being connected to the second front wall and to the second back wall; and
wherein the second front wall, the second back wall and the two second side walls are formed as a single casting;
wherein at least one of the first component and the second component further comprises at least one block located to prevent air from flowing through the at least one void.

28. A modular fan tray component, comprising:
a front wall;
a back wall;
two side walls, each side wall being connected to the front wall and to the back wall; the front wall, the back wall and the two side walls defining a volume;
a first inner wall at least partially disposed within the volume and defining a Venturi;
a fan at least partially disposed within the Venturi; and
a first mounting bracket adjacent one of the two side walls, the first mounting bracket having a first predefined cross-sectional profile;
wherein the other of the two side walls defines a first mounting bracket receiver having a second predefined cross-sectional profile.

29. A modular fan tray component as defined in claim 28, wherein the first cross-sectional profile is complementary to the second cross-sectional profile.

30. A modular fan tray component as defined in claim 25, wherein the back wall defines a second mounting bracket receiver having a third predefined cross-sectional profile.

31. A modular fan tray component as defined in claim 30, wherein:
the other of the two side walls has a length extending from the front wall to the back wall;
the first mounting bracket receiver extends along at least part of the length of the other of the two side walls;
the back wall has a length extending from one of the two side walls to the other of the two side walls; and
the second mounting bracket receiver extends along at least part of the length of the back wall.

32. A modular fan tray component as defined in claim 30, further comprising a second mounting bracket adjacent the front wall, the second mounting bracket having a fourth predefined cross-sectional profile.

33. A modular fan tray component as defined in claim 32, wherein the third cross-sectional profile is complementary to the fourth cross-sectional profile.

34. A dummy modular fan tray component, comprising:
a front wall;
a back wall;
two side walls, each side wall being connected to the front wall and to the back wall; the front wall, the back wall and the two side walls defining an area;
a partition blocking air flow through the area; and
a first mounting bracket adjacent one of the two side walls, the first mounting bracket having a predefined cross-sectional profile;
wherein the other of the two side walls defines a first mounting bracket receiver having a predefined cross-sectional profile.
